(19) United States
(12) Patent Application Publication
(10) Pub. No.: US 2012/0086467 A1
(43) Pub. Date: Apr. 12, 2012

(54) APPARATUS FOR SUPPORTING A DISK DRIVE AND DISK DRIVE TEST APPARATUS

(75) Inventors: Alexander Stephen Kay, Milton (GB); Stephen Andrew Bailey, Waterlooville (GB)

(73) Assignee: Xyratex Technology Limited, Havant, Hampshire (GB)

(21) Appl. No.: 13/375,413

(22) PCT Filed: May 18, 2010
(86) PCT No.: PCT/GB2010/050810

§ 371 Date: Nov. 30, 2011

Related U.S. Application Data
(60) Provisional application No. 61/184,453, filed on Jun. 5, 2009.

(51) Int. Cl. G01R 31/00; H05K 5/02; B23P 11/00

(52) U.S. Cl. 324/756.01; 29/428; 29/426.1; 312/237

(57) ABSTRACT

The invention provides a method and apparatus for inserting a disk drive into or removing a disk drive from a test cell, the test cell including plural slots, each slot having a carrier for receiving the disk drive, the method including: moving the carrier out of the slot into an open position so that it can receive a disk drive, wherein the carrier remains in contact with the slot; inserting a disk drive into the carrier when the tray is still in contact with the slot; and moving the carrier containing the disk drive into a closed position back in the slot.

The present invention relates to apparatus for supporting a disk drive, disk drive test apparatus for receiving plural disk drives and a method of testing a disk drive.

The present invention has particular application when testing a disk drive during the manufacturing process. However, the present invention has application to mounting of a disk drive during a servo-writing process (when servo tracks are written to the disk drive, including the case where a separate clock head is used as well as the self-servo writing process and the self-servo fill process), and during normal use of the disk drive by an end user.

Examples of arrangements for supporting a disk drive are disclosed in U.S. Pat. No. 6,018,437, WO-A-97/06532, WO-A-03/021597, WO-A-03/021598 and WO-A-2004/114286, the entire disclosures of which are hereby incorporated by reference. In many of these arrangements, the disk drive is supported in a carrier (or “tray”) which is inserted into and removed from a housing (or “chassis”). Typically, this insertion and removal is automated and is carried out by a robotic arm.

Typically in such a housing, plural slots are provided each for receiving a respective disk drive. The act of inserting or removing a disk drive in its carrier from the housing can cause vibrations and a shock event that can disturb disk drives in other of the slots. As test cells become fully asynchronous, i.e. the tests or actions performed on an individual disk drive are not necessarily the same as those performed on other disk drives within the test cell, there is a growing need to prevent dynamic events from influencing adjacent slots.

According to a first aspect of the present invention, there is provided a method of inserting a disk drive into a test rack, comprising a plural slots, each slot having a carrier for receiving the disk said disk drive and holding said disk drive in the slot, the method comprising sliding the carrier out of the slot so that it can receive a disk drive, wherein the carrier remains in contact with the slot; inserting a disk drive into the carrier when the tray is still in contact with the slot and then sliding the carrier back into the slot.

According to another aspect of the present invention, there is provided a method of removing a disk drive from a test cell, the test cell comprising plural slots, each slot having a carrier for receiving the said disk drive, the method comprising: moving the carrier containing a disk drive out its slot into an open position; and, removing a disk drive from the carrier when the carrier is still in contact with the slot.

A method is provided of inserting a disk drive into or removing a disk drive from a test rack, comprising plural slots in which during the insertion or removal of the disk drive, the carrier in which the disk drive is actually placed or taken from remains in contact with the slot. This is important. If two adjacent slots are considered, one in which a disk drive is currently under test, possibly even servo track writing, and the adjacent slot does not have a disk drive and is waiting for a drive to be placed into the slot, the action of inserting the drive into the slot will inevitably disturb the structure of the housing and thus the adjacent slot containing a disk drive under test. The slot which is under test will have to manage the disturbance. Conventionally this is done just with isolation systems that serve to isolate the slot from external vibrations and, vice versa, to ensure that vibrations generated within the slot are not transferred externally.

The slot that is conventionally receiving a carrier with a disk drive undergoes some displacement when the slot is supported by an isolation system. This displacement has historically been controlled by the isolators which offer some resistance thus damping the slot, or by other means such as air seal gaskets or hard stops such as plastic to plastic contact.

It has been recognised that the bulk of the shock event is the initial contact as the tray aligns to the slot. By ensuring that the carrier remains in contact with the slot when a disk drive is inserted into a slot, this shock event is eliminated. Indeed, the major shocks caused to adjacent slots by the insertion of a disk drive into a particular slot within a cell arise from the first engagement of the carrier with the vacant slot and the plugging of the drive into the slot, i.e. the connection between the drive and an interposer, usually at the back of the slot. This is usually because, as explained above, the insertion and removal is automated and is carried out by a robotic arm. There is some unavoidable impact on engagement between the robotic arm and the carrier and this is easily transferred to adjacent slots. Furthermore, if there is any misalignment between the carrier and the slot an impact between the edge of the carrier and the slot can cause vibration of the housing.

By requiring that the carrier remains in contact with the slot whilst a disk drive is placed in the carrier the disturbance to adjacent slots caused by the first engagement of the carrier with the slot is addressed.

As mentioned above, a slot that is conventionally receiving a carrier with a disk drive undergoes some displacement when the slot is supported by an isolation system. This displacement has historically been controlled by the isolators which offer some resistance, thus damping the slot, or by other means such as air seal gaskets or hard stops such as plastic to plastic contact. The isolation system thus needs to be robust enough to withstand repeated insertions of carriers and also able to damp down the insertion force.

According to a second aspect of the present invention, there is provided apparatus for supporting a disk drive that has a disk which rotates in use about a disk axis, the apparatus comprising:

a housing for receiving one or more movably supported slots;

at least one movably supported slot in which a disk drive can be received;

an isolation system to isolate the slot from other slots within the housing; and

a shock absorber provided between the housing and the slot, to absorb the impact on the slot of the disk drive when it is inserted into the slot, the shock absorber arranged to be out of contact with the housing during normal use and to contact the housing upon insertion of a disk drive into the slot.

The slot is provided with a shock absorber and an isolation system. The shock absorber is not arranged to be in contact with the housing during normal operation but in fact engages the housing only upon insertion of a disk drive or a carrier into the housing. Thus, apparatus is provided that enables a separation of the isolation that is required in normal use from the shock absorbing required during insertion of a disk drive to a test cell.

By providing dedicated means to satisfy the functions of shock absorption during insertion and isolation during normal use, no compromise in performance in either function is required. In other words, the dedicated shock absorber can be made robust enough to withstand insertions and also damp some of the insert of the insert force, whilst the isolation system can be made responsive enough to deal with the normal frequencies and magnitudes of vibrations encountered during normal use. The isolation system does not itself need to have the required strength to withstand the insertion process.

Preferably, the shock absorber comprises a boss protruding from the slot for engagement with a corresponding hole on the housing. Preferably, the boss has mounted over it material, such as an elastomer, to provide shock protection.

When the insertion or removal of a hard disk drive on a carrier occurs, the slot displaces slightly relative to the housing due to reaction of the isolation system until the carrier engages with the shock absorber. When the shock absorber is engaged, it offers further resistance, stiffness and damping until the insertion or removal of disk drive on the carrier has been completed. Once the automation has released its grip on the carrier the shock absorber locates within the opening in the housing out of contact with the housing. The slot is supported in normal use by the isolation system alone.

According to a further aspect of the present invention, there is provided apparatus for supporting a disk drive that has a disk which rotates in use, the apparatus comprising:

a housing for receiving one or more movably supported slots;

at least one movably supported slot arranged to receive a disk drive;

an isolation system to isolate the slot from other slots within the housing; and

a shock absorber provided between the housing and the slot, to absorb the impact on the slot of the disk drive when it is inserted into the slot.

Dedicated means is provided to satisfy the functions of shock absorption during insertion and isolation during normal use. Thus, no compromise in performance in either function is required. The dedicated shock absorber can be made robust enough to withstand insertions and also damp some of the insert of the insert force, whilst the isolation system can be made responsive enough to deal with the normal frequencies and magnitudes of vibrations encountered during normal use.

Embodiments of the present invention will now be described by way of example with reference to the accompanying drawings, in which:

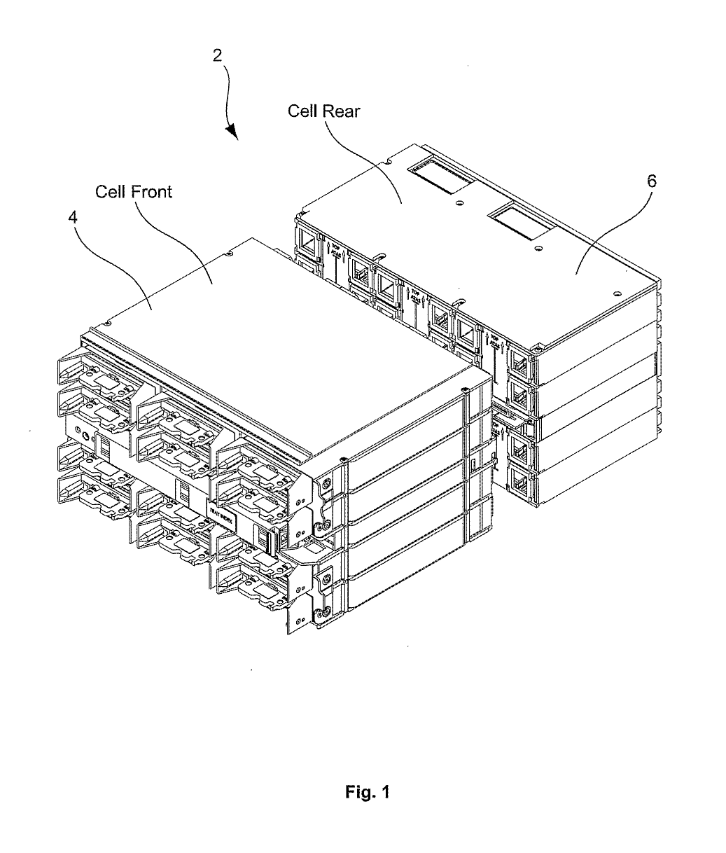

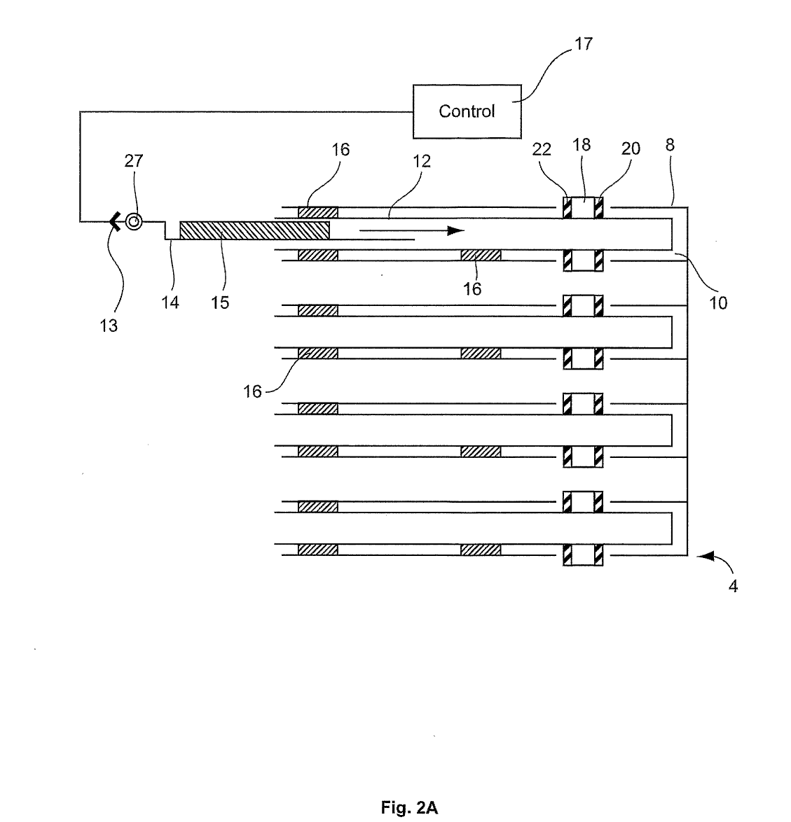

FIG. 1 shows schematically a perspective view of a disk drive test cell;

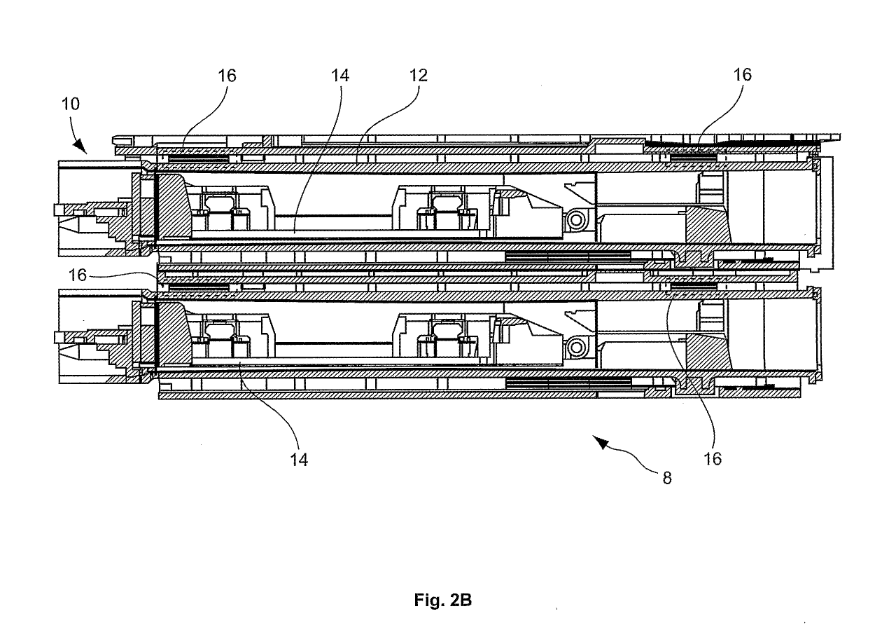

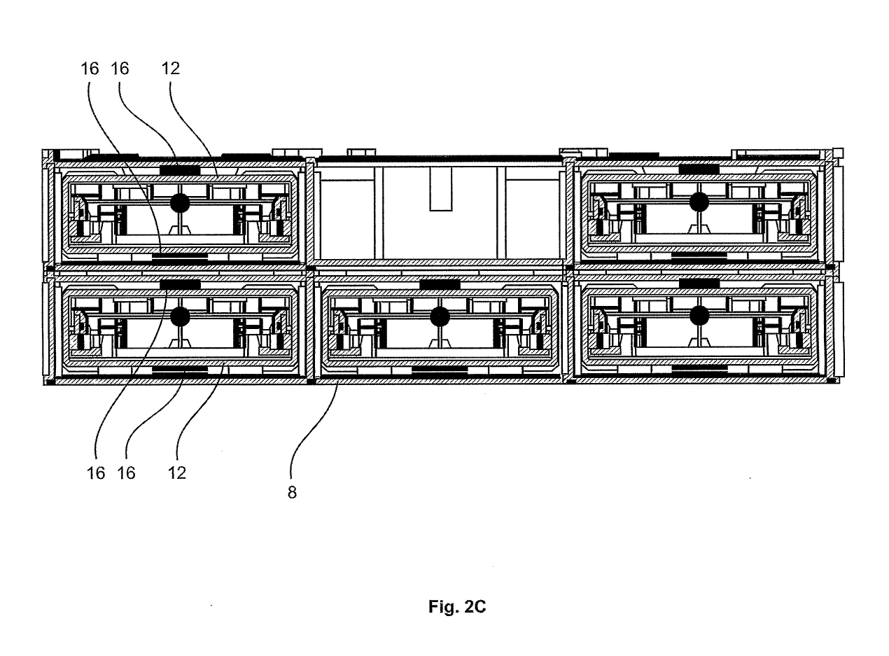

FIG. 2A shows schematically a vertical section through slots in the cell front of the disk drive test cell of FIG. 1;

FIG. 2B shows a longitudinal cross-section through two slots from a disk drive cell such as that shown in FIG. 1;

FIG. 2C shows a transverse cross-section through a 6-slot disk drive cell;

FIG. 3 shows schematically a slot from the cell of FIG. 1;

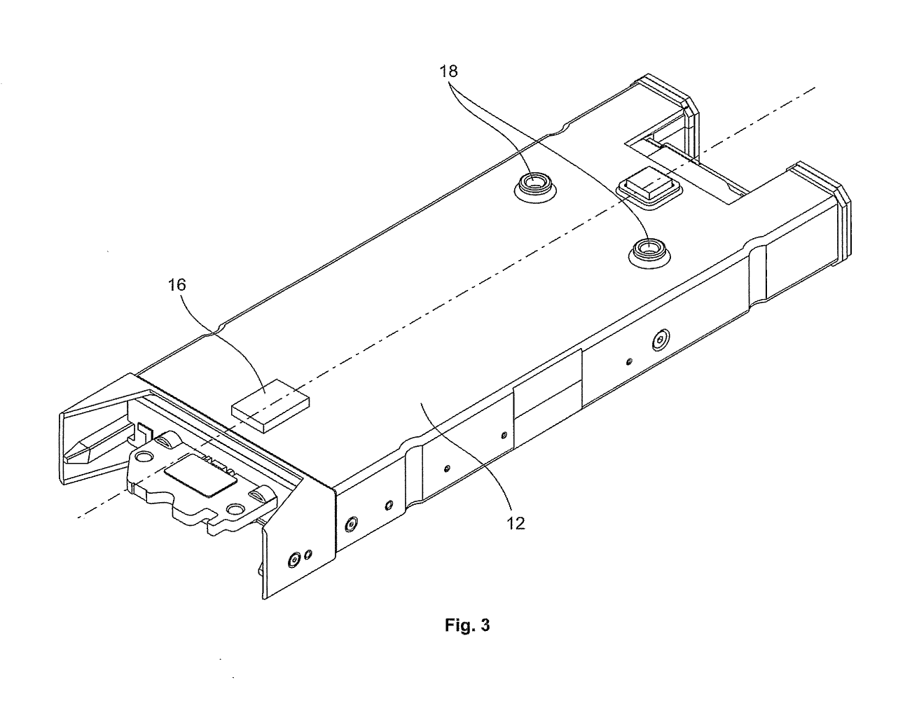

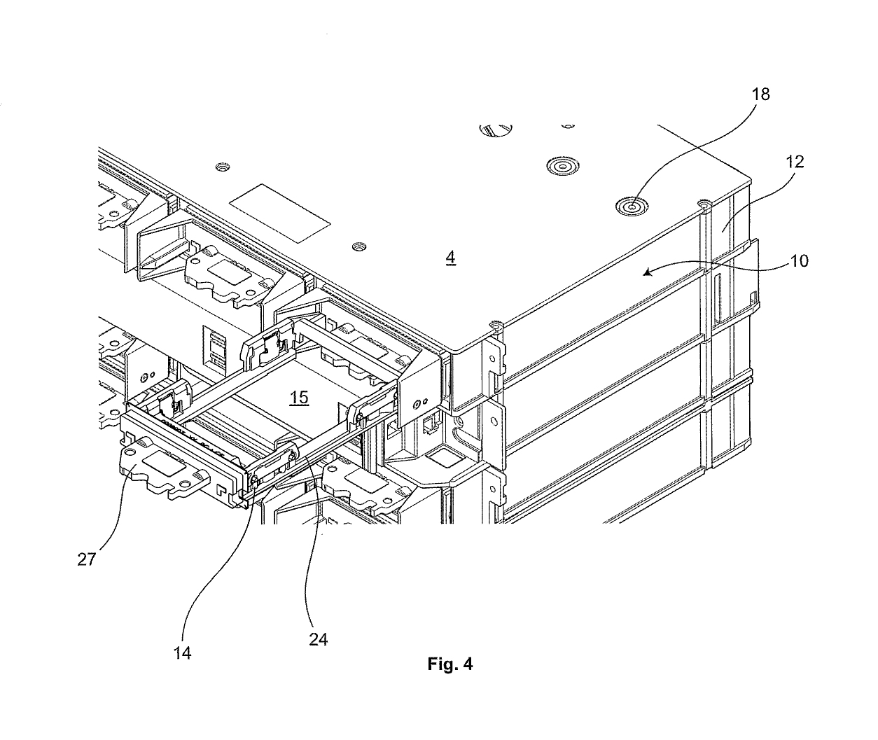

FIG. 4 shows schematically a perspective view of part of the disk drive test cell of FIG. 1 with a carrier tray in an open position;

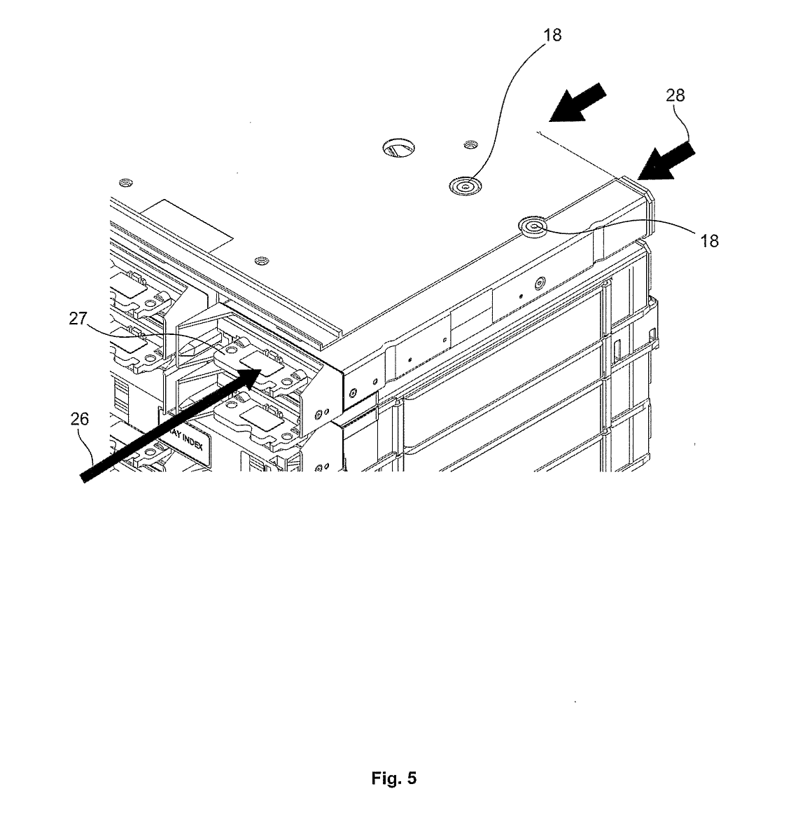

FIG. 5 shows schematically a perspective view of part of the disk drive test cell of FIG. 1 with a carrier tray in an closed position;

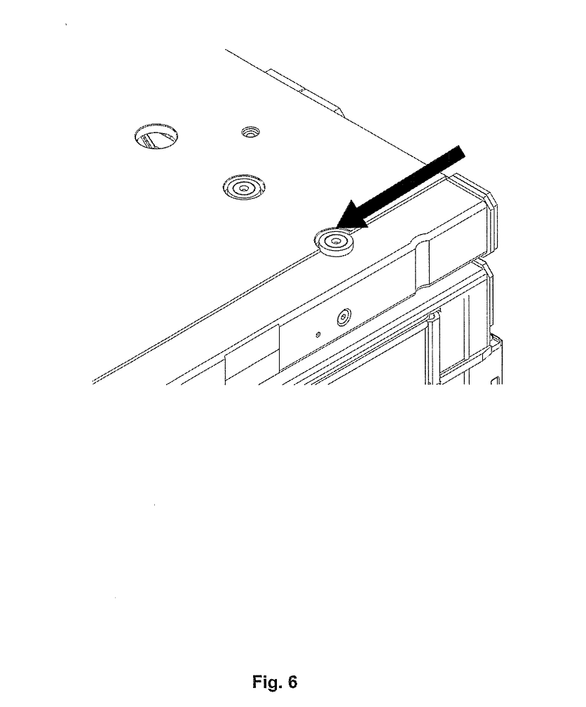

FIG. 6 shows schematically a perspective view of part of the disk drive test cell of FIG. 1 with a section of the top cover removed; and

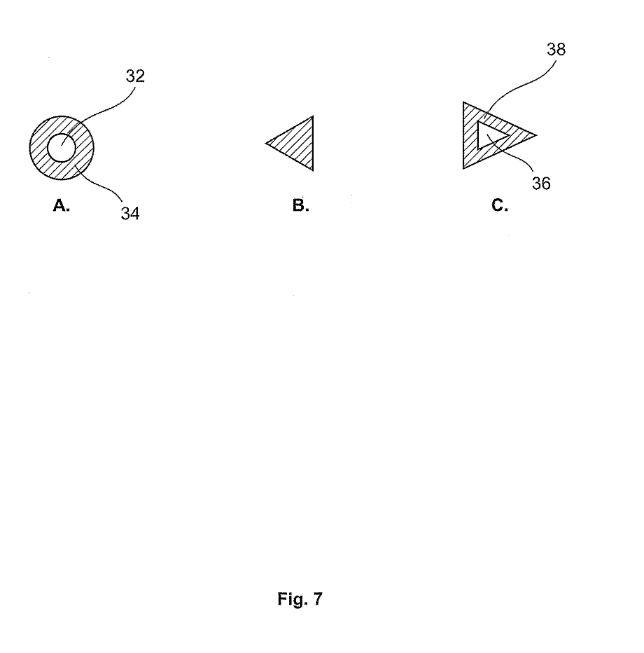

FIG. 7 shows in plan view a number of examples of shock absorbers for use with slots of a disk drive test cell.

FIG. 1 shows schematically a perspective view of a disk drive test cell. The test cell 2 comprises a front section 4 and a rear section 6. In use, the front 4 and back 6 sections of the test cell are held together when inserted into a test rack and are preferably independently grounded. With reference to FIG. 2A as well which shows a schematic vertical section through the front section 4 of the cell, the front section 4 comprises a chassis having plural bays 10 each arranged to receive a slot 12. The slots 12 are themselves arranged to receive disk drives 15, preferably on carriers 14. In the example shown in FIG. 2A, a disk drive 15 on a carrier 14 is being inserted into the uppermost slot 12 within the cell 4. It will be appreciated that, for clarity, the interface at the back of the slots 12 and bays 10 for connection of a disk drive or the carrier with the rear section 6 of the cell is not shown. In this example, there are 12 slots in two arrangements of 3×2.

Typically, a robot 13 or automation, is controlled by controller 17 to insert the tray in the direction of the arrow shown in FIG. 2. The robot is arranged to grip a gripping section 27 shown schematically at the front of the carrier 14. With use of the automation, there is inevitably an amount of error in alignment of a carrier or a disk drive with the slot opening. During repeated operation and cycles of insertion and removal of carriers 14 from slots 12, a slot can be knocked in such a way that, if unaddressed, the movement and vibration could have a deleterious effect on an adjacent or otherwise neighbouring slot within the cell.

Each of the slots 12 comprises an isolation system made up of isolators 16 which serve to provide some degree of isolation for a slot. The isolation system serves both to insulate the slot against vibrations from other slots and to insulate other slots from vibrations that it may cause during normal operation. In addition, a shock absorber 18 is provided coupled to the slot 12. In the example shown, a hole 20 is provided in the housing 8. The shock absorber 18 is arranged to protrude through the hole 20. In another embodiment the shock absorber in the form of a boss or projection may be provided on the chassis wall to protrude within one or more corresponding holes in the slot wall.

In the example shown in FIG. 2A, a shock absorber 18 is provided on both the upper and lower walls of the slot. In one embodiment, the shock absorber may also or alternatively be provided on one or both of the side walls of the slot, with corresponding openings being required in the appropriate chassis walls. The shock absorbers engage with the upper, lower or side walls of the slot. Only minimal, if any, insertion shock is absorbed through the back wall of the chassis. This is important as it is through the back wall that shock is most easily transferred between adjacent slots, as the back wall of the chassis is effectively shared between plural bays 10.

The isolators may be made of any suitable material such as elastomeric material. In one example the isolators include sheets of various soft elastomers and gels which do not contain silicon. The isolators may be the same for each isolator within the isolation system or isolators with different properties can be used to tune the performance to the isolation system in each dimension.

In this example, the shock absorber 18 comprises a boss 17 surrounded by a ring of material 22, which is preferably elastomeric thereby to improve the shock protection provided by the shock absorber 18.

In use, when a carrier 14 containing a hard disk drive 15 is inserted into the slot 12, the slot 12 is displaced on the isolation system 16 by a small amount until the shock absorber 18 engages the edge of the opening 20 in the chassis 8. Thus, when the shock absorber 18 engages the edge of the hole 20 an additional stiffness is provided over and above that provided by the contact between the slot 12 and the bay 10 through the isolation system 16. There is an additional stiffness offered by the shock absorber that offers further resistance, stiffness and damping until the insertion or removal of the carrier 14 with the disk drive 15 has been completed.

By providing a dedicated shock absorber to satisfy the requirement for shock absorption during carrier or disk drive insertion, no compromise in performance of the isolation system is required. In other words, the dedicated shock absorber can be made robust enough to withstand insertions and also damp some of the insert of the insert force, whilst the isolation system can be made responsive enough to deal with the normal frequencies and magnitudes of vibrations encountered during normal use. The isolation system does not itself need to have the required strength to withstand the carrier or disk drive insertion process.

The slot is provided with a shock absorber and an isolation system. The shock absorber is arranged to be out of contact with the housing during normal operation and typically engages the housing only upon insertion of a disk drive or a carrier into the slot. Thus, apparatus is provided that enables a separation of the isolation that is required in normal use from the shock absorption required during insertion of a disk drive to a test cell. The transmission of shock from one slot to an adjacent one is minimised prior to reaching the isolation system of the adjacent slot.

The structural rigidity of the material that offers the reaction against the shock absorber is clearly important to ensure minimising the shock transferred to an adjacent slot. Therefore, in the example shown, the boss 18 passes through an opening 20 in the chassis that absorbs the force in the plane that offers the maximum structural strength and rigidity. As mentioned above, this is preferably provided in the upper or lower walls of the slot. In one embodiment the chassis may be strengthened in the direction of insertion of a carrier such as to increase the structural strength and rigidity of the chassis in the plane that is arranged to absorb the force. For example, one or more longitudinal ribs or other such strengthening features may be provided in the chassis wall.

In normal operation of the disk drive test cell 2, the shock absorber 18 is not in contact with the chassis 8. Rather, the isolators 16 of the isolation system function as normal to provide isolation of a disk drive 15 within the slot 12. It can be seen that the shock absorber 18 has a small amount of movement prior to the slot being clamped in motion by the shock absorber. The reaction onto the lid of the cell is in the plane of the maximum stiffness of the cell lid.

The reaction force against displacement of the slot 12 due to insertion of a disk drive can be made to be non-linear if desired. This can be achieved by controlling the surface contact between the shock absorber 18 and the chassis 8 so that a progressively stiff contact is generated. In other words, the shock absorber can be constructed and arranged such that as the displacement of the slot 12 increases there is greater surface contact between the shock absorber 18 and the reaction surface of the chassis. This can be achieved by making the shape of the shock absorber to a desired configuration.

FIGS. 7A to 7C show plan views of some suitable examples. In FIG. 7A, a circular boss 32, i.e. a boss with circular cross-section, is provided with a correspondingly shaped cylindrical elastomeric surround 34. In FIG. 7C, a triangular boss 36 is provided with a correspondingly shaped elastomeric surround 38. As can be appreciated, as the shock absorber of FIG. 7C is compressed (starting from the right hand side), the resistance experienced will increase as does the width of the shock absorber. In FIG. 7B, the shock absorber is a solid piece of elastomeric material without any central structure like that of FIGS. 7A and 7C. The same or different materials may be used for the shock absorber as are used for the isolators 16 in the isolation system.

As can be seen from FIGS. 1 and 3, in a preferred embodiment, two shock absorbers 18 are used for each slot. This ensures that the plugging force and the reaction to it from the chassis 8 is distributed (preferably uniformly) across the cell, or at least across each slot 12 and corresponding bay 10, and also that the slot 12 does not damage or breach the isolation system made up of the isolators 16. Use of two shock absorbers in particular in this case maintains alignment or “squares up” a slot when a force is applied. This is beneficial in some cases, such as when a drive connector is mating to the slot.

A particular advantage of the use of shock absorbers of the type discussed above that are, in this example arranged to engage with the upper wall of the slot bay 10 is that an internal load is created on the cell front 2. This means that upon insertion of a disk drive 15, the rear portion 6 of the cell is not disturbed. If it were disturbed, then a greater influence might be exerted on an adjacent slot under test within its bay 10 in the front section 4.

The use of a shock absorber coupled to the slot 12 enables an easily tunable means for controlling the damping of the motion in such a way whereby the transmission of shock between adjacent slots can be minimised prior to the shock reaching the isolation system of an adjacent slot. Thus, an increased level of protection from external interruption is provided to adjacent slots. This is particularly important in an asynchronous system in which there is a need to prevent dynamic events, i.e. the insertion of a disk drive into one slot, from influencing the activity in an adjacent slot. In other words, in general, instead of an adjacent slot and disk drive therein having to rely only on the isolators 16 of the slot isolation system to protect the disk drive from external vibrations, the noise and shock is addressed at source, i.e. by the slot from which the disturbance arises.

FIG. 2B shows a longitudinal section through two slots in a disk drive cell such as that shown in FIG. 1. The slots 12 are arranged within a bay 10 of a chassis 8. As in the examples described above, slot isolators 16 are provided. The isolators above the slots 12 can be seen clearly. Each of the slots 12 is shown containing a carrier 14 for a disk drive (not shown).

Referring to FIG. 2C, the slots 12 can be seen in transverse cross-section arranged within the chassis 8. Isolators 16 are provided below and above the slots to provide isolation for the slots from the walls of the chassis 8. In both of FIGS. 2B and 2C, the shock absorbers 18 are not shown.

FIG. 4 shows schematically a perspective view of part of the disk drive test cell of FIG. 1 with a carrier tray 14 in an open position. As can be seen, the carrier tray 14 is able to receive a disk drive into a disk drive receiving region 24. The tray 14 remains in contact with the slot 12. In other words, in contrast to known arrangements for loading a disk drive into a test rack, in the example shown in FIG. 4, the tray, in the open position, is maintained in contact with the slot 12. In other words, the tray is shown in an orientation in which the drive is loaded, by retaining the tray in the slot.

This is significant. By ensuring that the tray remains aligned and in contact with the slot when the disk drive is placed into the tray, the need to engage the tray with the slot, if the disk drive had been loaded at a separate station, is obviated. When inserting a disk drive into a slot on a carrier or tray, the bulk of the shock event as experienced by adjacent slots is the initial contact as the tray aligns to the slot. In the example of FIG. 4, this shock is thus eliminated since the tray 14 never, in normal use, leaves contact with the slot 12. FIG. 5 shows a representation of the device of FIG. 4 in which the tray 14 is closed. The placing of a disk drive in a carrier tray is performed locally at the cell rather than at a separate station and thus a major shock event that is usually experienced is avoided.

Once a disk drive has been inserted, typically, a robot or automation inserts the tray in the direction of the arrow 26. Typically, the process of insertion of a disk drive into a slot would comprise the following steps. First, the carrier is opened. This can be achieved by a robot 13 or automation engaging with a carrier opening or gripping section 27. The carrier 14 is then pulled away from the housing and bay 10 until it is in a position such that the disk drive receiving portion 15 of the carrier can be easily accessed. Preferably, it has to be pulled out such that the whole of the disk drive is viewable from above. In this configuration, a robot could easily engage with the disk drive and lift it out. The carrier is not disconnected physically from the slot as shown in FIG. 4. In other words it remains coupled to the slot in normal use.

The disk drive 15 may then be removed from the carrier by a robot or manually if desired and a new disk drive put in in place. Once this has been done, the robot pushes the carrier or drawer forwards into the slot. The automation inserts the tray resulting in a force in the direction represented by the arrow 26. This might cause the slot to move backwards slightly within its associated bay.

In the examples shown, and as explained above, shock absorbers 18 may be provided. The presence of the shock absorbers prevents the majority of the shock being passed through the gaskets to the rear of the cell and then passed to the adjacent slot. Arrows 28 indicate the reaction force that would be provided by the rear of the cell were the shock absorbers not provided. In other words, the arrows 28 represent the reaction to be minimised at the rear of the cell front. This reaction force would be passed to adjacent slots. Therefore, by providing the shock absorbers 18, the effect of the insertion of the disk drive into the slot on the adjacent slot is substantially reduced.

Embodiments of the present invention have been described with particular reference to the examples illustrated. However, it will be appreciated that variations and modifications may be made to the examples described within the scope of the present invention.

1. A method of inserting a disk drive into a test cell, the test cell comprising plural slots, each slot having a carrier for receiving the said disk drive, the method comprising:
moving the carrier out of the slot into an open position so that it can receive a disk drive, wherein the carrier remains in contact with the slot;
inserting a disk drive into the carrier when the carrier is still in contact with the slot; and
moving the carrier containing the disk drive into a closed position back in the slot.

2. A method according to claim 1, wherein moving the carrier out of the slot comprises engaging a front section of the carrier with a robot and controlling the robot to move the carrier into the open position.

3. A method according to claim 1, wherein moving the carrier containing the disk drive back into the slot comprises engaging a front section of the carrier with a robot and controlling the robot to move the carrier into the closed position.

4. A method of removing a disk drive from a test cell, the test cell comprising plural slots, each slot having a carrier for receiving the said disk drive, the method comprising:
moving the carrier containing a disk drive out its slot into an open position; and,
removing a disk drive from the carrier when the carrier is still in contact with the slot.

5. A method according to claim 4, in which the step of moving the carrier containing a disk drive into the open position comprises moving it far enough out such that the entire disk drive can be seen from above.

6. Disk drive test apparatus for receiving plural disk drives, the apparatus comprising plural slots, each slot containing a carrier arranged for movement between a closed position in which the carrier is contained within the slot and an open position in which the carrier is exposed and able to receive or have taken from it a disk drive, the apparatus being configured and arranged such that, in the open position, the carrier remains connected to the slot.

7. Apparatus according to claim 6, in which the carriers are fixed so that they cannot be removed from the slots in the open position.

8. Apparatus according to claim 6, in which the carriers each have a gripping section at the front for engagement with a gripper to move the carrier between the closed and open positions.

9. Apparatus according to claim 8, comprising automation for engagement with the gripping section to move the carrier between the open and closed positions.

10. Apparatus according to claim 9, wherein the automation is configured and controlled such that it cannot break the contact between the slot and the carrier.

11. Apparatus for supporting a disk drive that has a disk which rotates in use, the apparatus comprising:
a housing for receiving one or more movably supported slots;
at least one movably supported slot arranged to receive a disk drive;
an isolation system to isolate the slot from other slots within the housing; and
a shock absorber provided between the housing and the slot, to absorb the impact on the slot of the disk drive when it is inserted into the slot, the shock absorber arranged to be out of contact with the housing during normal use and to contact the housing upon insertion of a disk drive into the slot.

12. Apparatus according to claim 11, in which the shock absorber is coupled to the slot and arranged to engage with a corresponding component on the housing to absorb the impact of the insertion of a disk drive.

13. Apparatus according to claim 11, in which the shock absorber comprises a projection coupled to the slot arranged within an opening in the housing wall such that upon movement of the slot with respect to the housing, the projection engages the opening in the wall thereby to absorb the shock of the impact.

14. Apparatus according to claim 11, in which the shock absorber comprises a projection provided on the housing arranged to extend into an opening on the slot such that upon movement of the slot relative to the housing during insertion of a carrier, the projection engages with the opening thereby to absorb shock of the impact.

15. Apparatus according to claim 12, in which the projection comprises a boss having a shock absorbing coating.

16. Apparatus according to claim 15, in which the shape of the projection is configured such as to enable a variation in the reaction force from the opening with which the projection engages.

17. Apparatus according to claim 11, in which the housing comprises plural bays, each containing a movably supported slot, wherein the bays have bay walls containing openings to receive the shock absorber such that shock is imparted to one or more of the side walls, the top wall and the bottom wall of the respective bays.

18. Apparatus according to claim 7, in which the carriers each have a gripping section at the front for engagement with a gripper to move the carrier between the closed and open positions.

19. Apparatus according to claim 13, in which the projection comprises a boss having a shock absorbing coating.

20. Apparatus according to claim 13, in which the housing comprises plural bays, each containing a movably supported slot, wherein the bays have bay walls containing openings to receive the shock absorber such that shock is imparted to one or more of the side walls, the top wall and the bottom wall of the respective bays.
